(19) United States
(12) Patent Application Publication
(10) Pub. No.: US 2012/0199187 A1
(43) Pub. Date: Aug. 9, 2012

(54) NANOWIRE TUNNEL DIODE AND METHOD FOR MAKING THE SAME

(75) Inventors: Magnus Borgström, Lund (SE); Magnus Heurlin, Lund (SE); Stefan Fält, Copenhagen N (DK)

(73) Assignee: Sol Voltaics AB, Lund (SE)

(21) Appl. No.: 13/503,314

(22) PCT Filed: Oct. 22, 2010
(86) PCT No.: PCT/SE2010/051147

§ 371 Date: Apr. 20, 2012

(30) Foreign Application Priority Data
Oct. 22, 2009 (SE) 0950781-5

(51) Int. Cl. H01L 31/0352; H01L 21/329; H01L 29/88; B82Y 99/00

(52) U.S. Cl. 136/255; 257/104; 438/478; 257/E29.339; 257/E21.353; 977/948

(57) ABSTRACT

The present invention provides a tunnel diode and a method for manufacturing thereof. The tunnel diode comprises a p-doped semiconductor region and an n-doped semiconductor region forming a pn-junction at least partly within a nanowire where semiconductor materials on different sides of the pn-junction are different such that a heterojuction is formed. The materials of the nanowire may be compound semiconductor materials. The heterojunction tunnel diode can be of type-I (Straddling gap), type-II (Staggered gap) or type-III (Broken gap).

### TECHNICAL FIELD OF THE INVENTION

The present invention relates to semiconductor tunnel diodes, and in particular to tunnel diodes made using nanowires.

### BACKGROUND OF THE INVENTION

Half a century since its invention by Leo Esaki, the tunnel diode is receiving continued interest. However, while the tunnel diode was considered to have a promise that rivaled the transistor, it has realized far from that in real-world applications.

The functionality of the tunnel diode is based on interband tunneling of charge carriers. In its most simple form, the tunnel diode is made up by two layers of degenerately doped semiconductor material of different doping types in contact. Hereinafter, n++ will denote degenerate doping with donors and p++ degenerate doping with acceptors. FIG. 1 schematically illustrates the current (A) through the tunnel diode when a voltage (V) is applied across the junction made up by these layers. When forward biased the current first increases up to a peak current, I_{P}, as the voltage increases up to a peak voltage, V_{P}, where a further increase in voltage up to a valley voltage, V_{V}, results in a decrease of the current down to a valley current, I_{V}.

As the semiconductor materials on each side of the junction are degenerately doped, the Fermi level will be in the conduction band for the n++ side, and in the valence band for the p++ side. This leads to charge carriers on each side of the junction having the same energy and opposite charge, thereby allowing tunneling and subsequent annihilation of the charge carriers.

FIG. 2 in a)-d) schematically illustrates the band diagram for points A-D as indicated in FIG. 1, respectively. E_{C} is the conduction band energy, E_{V} is the valence band energy, E_{F} is the Fermi level energy, E_{Fn} and E_{Fp} are the Fermi level energy for the n-type and p-type sides of the junction with an applied voltage, respectively. As the voltage is increased, the tunneling through the junction will be directed by the energy difference between E_{Fn} and E_{Fp}. The tunneling rate scales inversely exponential both to the height of the barrier made by the band gap between the conduction band and the valence band, as well as the thickness of the barrier. The thickness is given by the depletion region width, which is given by the doping concentration in the material. Also, the electron and hole masses are important for the tunneling rate. In point A, at zero voltage, the junction function as an ohmic resistance, and in this analogue, the resistance is inversely proportional to the tunneling rate.

In point B, at V_{P}, the applied voltage over the junction result in maximum overlap of free electrons in the conduction band and free holes in the valence band at the same energies. At this point, the current is at a local maximum and when the voltage is further increased, exemplified in by point C, this overlap is decreased and the current is reduced. However, with an even higher voltage, as exemplified in point D, the situation of a normal diode in the forward bias regime is reached, where an increase in voltage is accompanied by an increase in current.

Decreasing current with increasing voltage means that the junction exhibits negative differential resistance (NDR). This is the feature that rendered the invention of the tunnel diode such attention, and has allowed the application in several different fields. Tunnel diodes have been used for oscillators, amplifiers, heterojunction bipolar transistors, as well as pressure gauges and light emitting diodes. Other applications for tunnel diodes are in low-power memory cells, so-called tunneling SRAMs, and in latches monolithically integrated with a standard CMOS process, as well as for interconnects in monolithically integrated multi-junction solar cells.

Although a great potential benefit in many applications the use of tunnel diodes is limited due to unsatisfactory performance primarily due to technical barriers in fabrication. Fabrication of prior art tunnel diodes is commonly based on epitaxial thin film growth and photolithography and etching, and hence, tunnel diodes are primarily made in Si, Ge and GaAs based materials and the scalability is limited.

Compound semiconductor tunnel diodes, such as those made of GaAs, are not readily integrated on preferred silicon substrates. Nevertheless this has been demonstrated with complicated and expensive processing such as wafer bonding or metamorphic growth on patterned substrates.

### SUMMARY OF THE INVENTION

In view of the foregoing one object of the invention is to provide improved tunnel diodes.

Hence a new approach for making tunnel diodes is provided. This new approach involves growth of a nanowire comprising doped semiconductor materials that form a tunnel diode or at least part of a tunnel diode. A tunnel diode according to the invention comprises a p-doped semiconductor region and an n-doped semiconductor region forming a pn-junction. The pn-junction is formed at least partly within a nanowire, either in an axial or a core-shell configuration. Preferably the p-doped semiconductor region comprises a degenerately doped p++ segment adjacent to a degenerately doped n++ segment of the n-doped semiconductor region.

The semiconductor materials of the tunnel diode can be chosen so that they are the same on both sides of a junction, i.e. a homojunction device. It is also possible to have different semiconductor materials on different sides of the junction i.e. a heterojunction device. In this case, there are different types of material combinations, resulting in type-I (straddling gap) or type-II (staggered gap) combinations, wherein the a n++ segment is grown on a p++ segment or a p++ segment is grown on a n++ segment. Another possibility is to combine materials so that the conduction band energy for the material on one of the sides of the junction is lower than the valence band energy for the material on the other side of the junction. This is a type-III (broken gap) heterojunction, which does not require degenerate doping.

The nanowire geometry allows strain relaxation via the surface, allowing for a much broader range of heterostructure combinations than for thin-film growth as the requirement for lattice matching is essentially removed. This opens up the potential of using type-II and type-III material combinations that cannot formed by prior art techniques. These material combinations have the promise of much better performance due to the reduced tunnel barrier height. Additionally, heterostructures forming quantum wells at one or both sides of the junction may be utilized, forming a so-called resonant interband tunnel diode. Reduced lattice mismatch requirements also opens up for growth of compound semiconductors on semiconductor substrates not readily made with prior art techniques, such as III-V semiconductors on Si.

The present invention provides tunnel diodes made of compound semiconductor materials selected from the group of: Ga, P, In, As, thereby forming type-I (Straddling gap) heterojunction tunnel diodes or type-II (Staggered gap) heterojunction tunnel diodes. By introducing Sb-based compound semiconductors type-III (Broken gap) heterojunction tunnel diodes can be formed. These type of tunnel diodes improves the transmission properties of the tunnel diode. In nanowires the Sb content can be increased to levels not possible in prior art technology, i.e. binary, ternary, quaternary and quinary Sb-base compounds can be formed and combined with other semiconductor compounds although the lattice mismatch may be significant. Such high Sb content would be detrimental in many prior art devices, in particular for optoelectronic devices since light would be absorbed in a region of high Sb content.

A method of manufacturing a tunnel diode is also provided. The method comprises the steps of providing a semiconductor substrate; growing a nanowire on the semiconductor substrate, whereby a pn-junction 6 comprising a p-doped semiconductor region 4 and an n-doped semiconductor region 5 at least partly within the nanowire 1 is formed.

For the emerging field of nanowire photovoltaics, tunnel diodes are a required building block to render nanowire multi junction solar cells possible. Hence a multi junction solar cell comprising the tunnel diode according to the invention is provided.

Thanks to the invention is possible to introduce lower bandgap material that is more susceptible to band bending from doping.

It is a further advantage of the invention that it is possible to use material combinations with band alignment that gives, or at least supports, the creation of a tunnel diode by doping.

It is a yet further advantage of the invention that it is possible to choose materials that are highly susceptible to either p or n doping in order to fabricate the tunnel diode.

A fundamental feature of nanowires is the narrow lateral size and the epitaxial, potentially defect-free, growth. The bottom-up approach of nanowire growth is easily scalable to smaller diameters and avoids the defects often induced in top-down processes based on etching.

Embodiments of the invention are defined in the dependent claims. Other objects, advantages and novel features of the invention will become apparent from the following detailed description of the invention when considered in conjunction with the accompanying drawings and claims.

### BRIEF DESCRIPTION OF THE DRAWINGS

Preferred embodiments of the invention will now be described with reference to the accompanying drawings, wherein:

FIG. 1 schematically illustrates the VI curve for a tunnel diode;

FIGS. 2a-d schematically illustrate band diagrams for different points (A)-(D) representing different properties of the tunnel diode points, in (A) ohmic resistance, in (B) current maximum, in (C) negative differential resistance, and in (D) normal diode in forward bias;

FIG. 3 schematically illustrates a nanowire tunnel diode in axial configuration according to the invention;

FIG. 4 schematically illustrates a nanowire tunnel diode in core-shell configuration according to the invention;

FIG. 5 schematically illustrates different tunnel diode configurations according to the invention;

FIG. 6 schematically illustrates a chart of different materials combinations for a tunnel diode according to the invention;

FIG. 7 schematically illustrates different III-V compound tunnel diode junctions according to the invention;

FIG. 8 schematically illustrates different compound tunnel diode junctions comprising Sb according to the invention;

FIG. 9 is a schematic diagram of the growth process of example 1 according to the invention;

FIG. 10 shows a measurement of the current through a single nanowire with light (solid line) and without (dash-dot) in accordance with example 1 according to the invention

FIG. 11 shows a SEM picture (left) of nanowire heterojunction tunnel diodes made up by n-type InP and (right) a VI curve for a single nanowire.

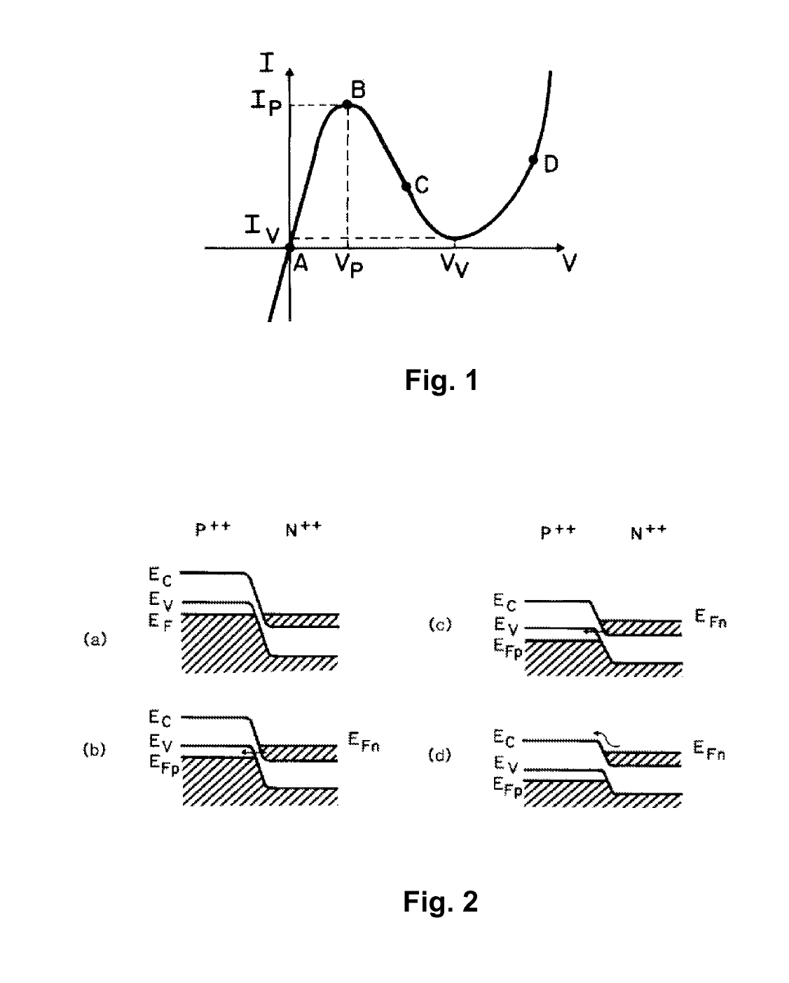

### DETAILED DESCRIPTION OF EMBODIMENTS

For the purpose of this application the term nanowire is to be interpreted as a structure being essentially of nanometer dimensions in its width or diameter. Such structures are commonly also referred to as nanowhiskers, nanorods, etc. The basic process of nanowire formation on substrates by particle assisted growth or the so-called VLS (vapour-liquid-solid) mechanism described in U.S. Pat. No. 7,335,908, as well as different types of Chemical Beam Epitaxy and Vapour Phase Epitaxy methods, which are well known. However, the present invention is limited to neither such nanowires nor the VLS process. Other suitable methods for growing nanowires are known in the art and is for example shown in international application No. WO 2007/102781. From this it follows that nanowires may be grown without the use of a particle as a catalyst. Thus selectively grown nanowires and nanostructures, etched structures, other nanowires, and structures fabricated from nanowires are also included.

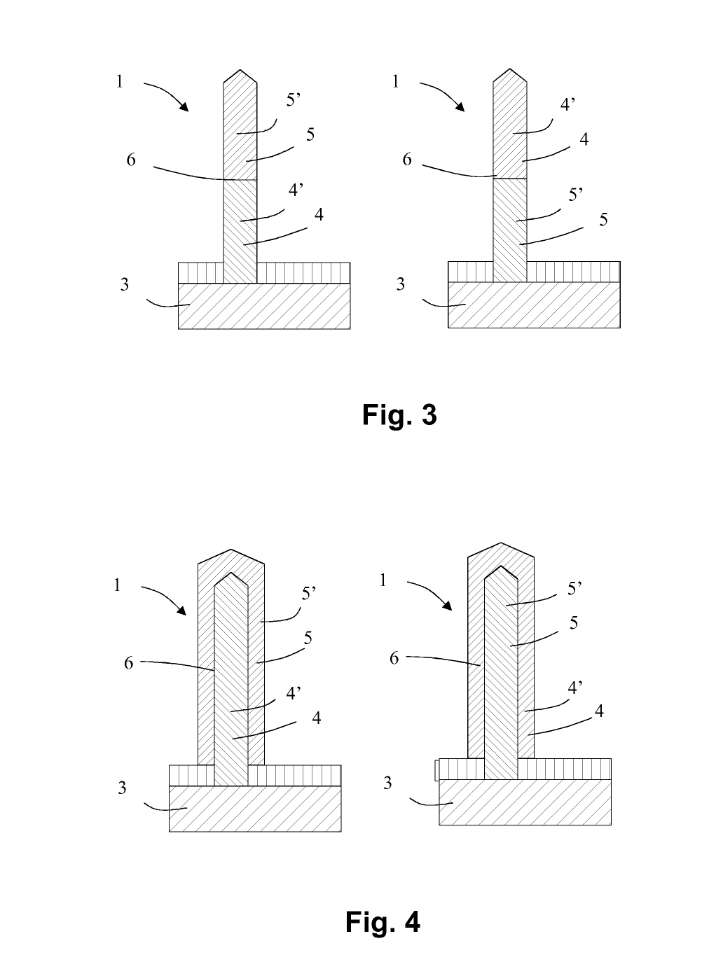

With reference to FIGS. 3-4, a tunnel diode according to the invention comprises a p-doped semiconductor region 4 and an n-doped semiconductor region 5 forming a pn-junction 6. The pn-junction 6 is formed at least partly within a nanowire 1, either in an axial or a core-shell configuration. Preferably the p-doped semiconductor region 4 comprises a degenerately doped p++ segment 4′ adjacent to a degenerately doped n++ segment 5′ of the n-doped semiconductor region 5, however not limited to this, as explained in the following. In principle, the functionality of the tunnel diode is as described in the background. During operation the tunnel diode has to be connected to terminals arranged at end portions of the tunnel diode in order to apply a voltage over the tunnel diode.

The nanowire 1 is grown from an upper surface of a semiconductor substrate 3 and when the semiconductor substrate 3 forms part of the tunnel diode or a semiconductor device comprising the tunnel diode the nanowire 1 protrudes from the semiconductor substrate 3 in a direction parallel with a normal direction, or in an pre-determined inclined relationship, with of the surface. The substrate 3 may be only a passive carrier for the nanowire 1 or part of an electrical circuit comprising the tunnel diode, for example being functional as one of the connecting terminals or forming part of the pn-junction. As appreciated from these examples the semiconductor substrate 3 itself has to be doped or provided with a doped, or conductive, layer at the upper surface. Such layers are commonly referred to as buffer layers.

With reference to FIG. 3, a tunnel diode with an axial configuration comprises at least a degenerately doped p++ segment 4′ epitaxially grown on a degenerately doped n++ segment 5′ within a nanowire 1 that protrudes from an upper surface of a semiconductor substrate 3.

With reference to FIG. 4, a tunnel diode with a core-shell configuration comprises a degenerately doped p++ segment 4′ epitaxially grown as a shell 8 enclosing at least a portion of a degenerately doped n++ segment 4′ of a nanowire core 9.

FIGS. 3 and 4 illustrates one embodiment where the nanowire 1 is electrically connected to the substrate 3 and a dielectric layer is arranged on the upper surface, however not limited to this. Optionally the nanowires 1 of FIGS. 3 and 4 comprises additional segments of different doping and/or composition arranged along the length of the nanowire and/or radially enclosing at least a portion of the nanowire in a core-shell configuration in order to form functional parts analogous to different semiconductor devices such as field-effect transistors, photodetectors, light emitting diodes, etc.

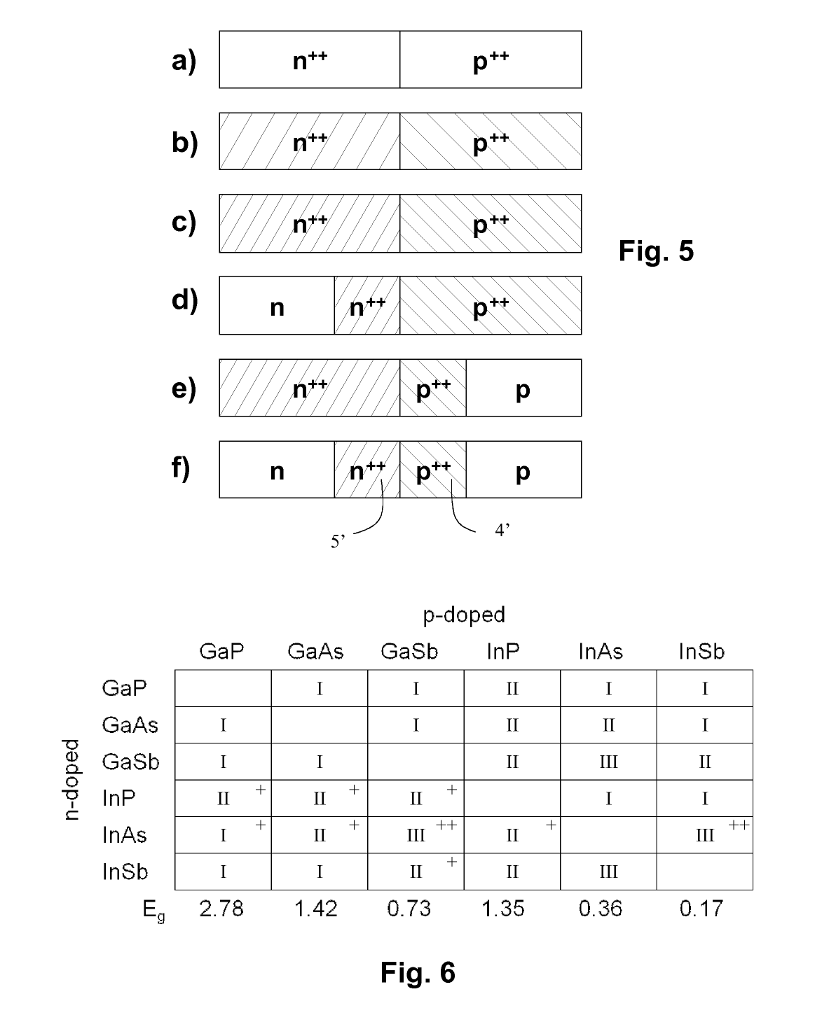

With reference to FIG. 5, the semiconductor materials of the tunnel diode can be chosen to be the same on both sides of a junction, i.e. forming a homojunction as schematically illustrated in FIG. 5a, or to have different semiconductor materials on different sides of the junction i.e. forming a heterojunction as schematically illustrated in FIG. 5b-f. In this case, there are different types of material combinations, resulting in type-I (straddling gap) or type-II (staggered gap) combinations, wherein the a n++ segment is grown on a p++ segment or a p++ segment is grown on a n++ segment. Another possibility is to combine materials so that the conduction band energy for the material on one of the sides of the junction is lower than the valence band energy for the material on the other side of the junction, resulting in type-III (broken gap) heterojunction. The junction may comprise some intermediate layer of different composition, i.e. at least one of the segments 4′, 5′ comprises a sub-segment in an end portion adjacent to the other segment 4′, 5′, as long as this does not significantly affect the tunneling properties. Due to a broader range of heterostructure combinations than possible for prior art thin-film growth, the requirements on the doping are moderate, and for some heterostructure combinations degenerate doping is not required. Normally a doping of 10²⁰-10²¹ cm⁻³ is required. While showing the segments forming the tunnel in an axial configuration the heterostructure combinations shown in FIG. 5 are also applicable for a core-shell configuration.

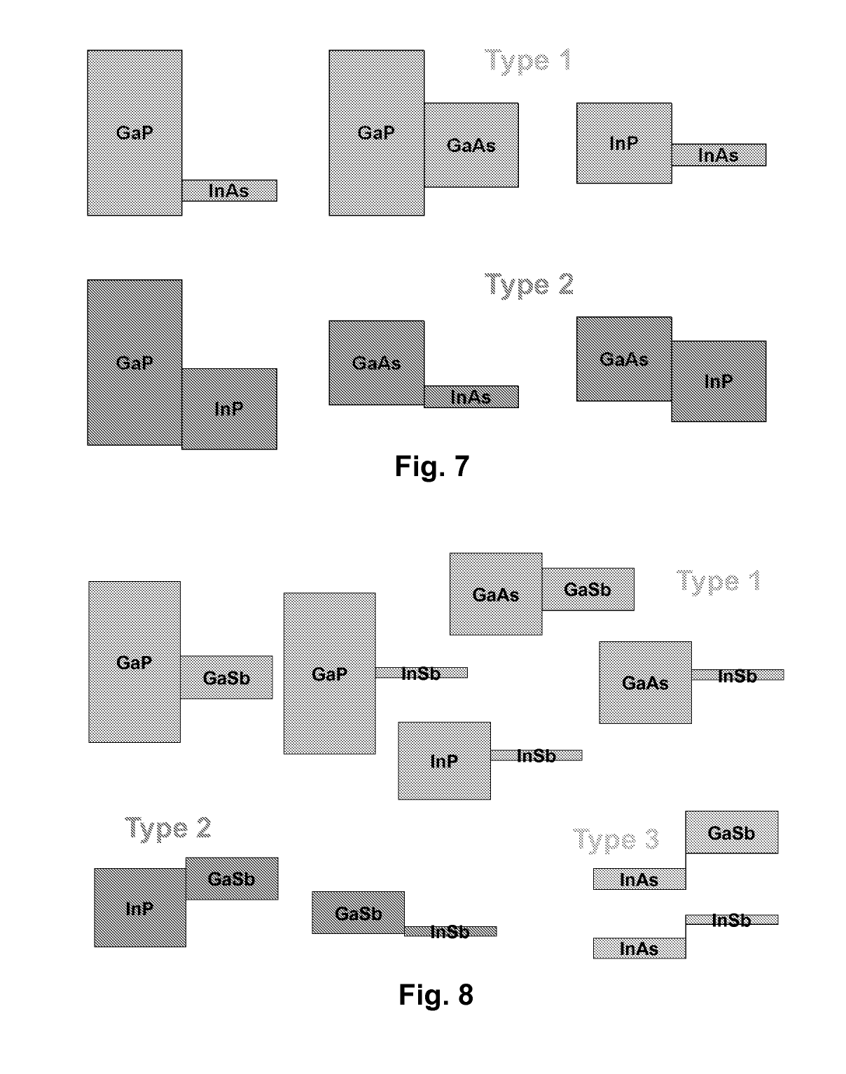

With reference to FIG. 5b, in one embodiment the tunnel diode comprises at least a degenerately doped n++ segment 5′ epitaxially connected to a degenerately doped p++ segment 4′. In one implementation of this embodiment the heterostructure junction of type-I or type-II is formed by InGaAsP-materials. Type-I heterojunctions shown in FIG. 7 are p++ GaP/n++InAs, p++ GaP/n++ GaAs and p++ InP/n++ InAs and type-II heterojunctions shown in FIG. 7 are p++ GaP/n++ InP, p++ GaAs/n++ InAs and p++ GaAs/n++ InP, whereof preferred combinations are type-I p++ InP/n++ InAs and type-II p++ GaP/n++ InP, p++ GaAs/n++ InAs and p++ GaAs/n++ InP.

With reference to FIG. 6, suitable semiconductor materials for the tunnel diode include, but are not limited to, combinations of binary, ternary, quaternary and quinary compound semiconductors from the group of Ga, P, In, As, Sb. The compound semiconductors may also include Al. The band gap, E_{g}, of the exemplified materials are GaP 2.78 eV, GaAs 1.42 eV, GaSb 0.73 eV, InP 1.35 eV, InAs 0.36 eV, InSb 0.17 eV. The chart of FIG. 6 and the examples of FIGS. 7-8 gives an overview of suitable heterostructure combinations for the tunnel diode. The heterostructure combinations comprising a Sb-based material, schematically illustrated in FIG. 8, are of particular interest. Preferred compound semiconductor combinations are the type-I combinations n++ InAs/p++ GaP and n++ InAs /p++ InP as well as the type-II combinations n++ InP/p++ GaP, n++ InP/p++ GaAs, n++ InP/p++ GaSb, n++ InAs/p++ GaAs and n++ InSb/p++ GaSb. Further preferred combinations are the type-III combinations n- or i-type InAs/p- or i-type GaSb and n- or i-type InAs/p- or i-type InSb. In the chart preferred combinations are indicated by a “+”-sign, and more preferred materials are indicated by a “++”-sign.

With reference to FIG. 5c, in one embodiment the tunnel diode comprises at least a degenerately doped n++ segment 5′ epitaxially connected to a degenerately doped p++ segment 4′. In one implementation of this embodiment the heterostructure junction is formed by InGaAsSbP-materials. Type-I heterojunctions shown in FIG. 8 are p++ GaP/n++ GaSb, p++ GaP/n++ InSb, p++ GaAs/n++ GaSb, p++ InP/n++ InSb and p++ GaAs/n++ InSb. Type-II heterojunctions shown in FIG. 8 are p++ InP/n++ GaSb and p++ GaSb/n++ InSb. Type-III heterojunctions shown in FIG. 8 are p++ InAs/n++ GaSb and p++ InAs/n++ InSb. As mentioned above the requirements on doping for these type III heterojunction segments are moderate as compared to prior art technology.

With reference to FIG. 5d-f, a tunnel diode comprising a heterojunction formed by adjacent degenerately doped segments in accordance with the invention may comprise one or more additional segments of different doping and/or composition in connection to the degenerately doped segments. For example, as shown in FIGS. 5d-e, a n/p-doped segment having significantly lower doping level, optionally of different material composition, is placed adjacent to a n++/p++ degenerately doped segment, or as shown in FIG. 5f, a n and p-doped segments having significantly lower doping level, optionally of different material composition, placed adjacent to a the n++ and p++ degenerately doped segment, respectively.

Basically, suitable methods for growing nanowires are known in the art and is for example shown in PCT application No. WO 2007/102781, incorporated by reference.

A method for manufacturing a tunnel diode according to the invention comprises the steps of:
providing a semiconductor substrate 3; and
growing a nanowire 1 on the semiconductor substrate 3, whereby a pn-junction 6 comprising a p-doped semiconductor region 4 and an n-doped semiconductor region 5 at least partly within the nanowire 1 is formed.

Nanowire growth is initiated by supplying suitable precursor gases. Material composition may be varied by changing the concentration or the composition of these gases during growth. The step of growing preferably further comprises the step of degenerately doping at least a p++ segment 4′ of the p-doped region 4 and a n++ segment 5′ of the n-doped region 5. The doping may be accomplished by supplying the dopant in gas phase during growth.

Suitable precursor gases for formation of the nanowires and nanowire segments comprising compound semiconductors made of InGaAsSbP-materials include, but are not limited to: AsH3, TBP, TBAs, TMIn, TMGa, TEGa, TESb, and TMSb. Suitable gases for doping include, but are not limited to: DMZn, DEZn, TESn, H₂S, and H₂Se.

### EXAMPLE 1

In this example, a homojunction tunnel diode is demonstrated. Further the example demonstrates how two diodes, acting as photovoltaic cells, in an InP nanowire are monolithically contacted with the tunnel diode. The nanowire was nucleated on a Si substrate in accordance with techniques according to prior art, and the growth of the nanowire was then continued, comprising the following steps:

1. Precursor molecules TMIn, PH3 and TESn were supplied to the growth reactor. TMIn and PH3 are the precursors for the InP, while Sn is incorporated from the TESn precursor, resulting in n-doping of the InP. A small flow of HCl was added to the gas mixture to remove any growth on the sidewall of the nanowire. This flow was maintained throughout the growth of the wire.

2. The flow of TESn was turned off and a short region without intentional doping was grown.

3. A flow of DEZn was added to the gas mixture in the growth reactor to achieve an extrinsic p-doped region.

4. The DEZn flow was turned up to increase the incorporation of Zn, resulting in a section with substantially higher doping level. This is the first section of the tunnel diode. The DEZn flow was chosen so that only a small increase would have resulted in a loss of epitaxial growth of the nanowire. Thus, the flow of DEZn was enough to reach degenerate doping in spite of the surface pinning of InP, which is beneficial for n-type doping rather than p-type doping.

5. For the second layer of the tunnel diode, the DEZn flow was turned off completely, and a large flow of TESn was immediately turned on instead. As Sn can be incorporated in InP nanowires to a very high level without losing epitaxial growth, it was possible to achieve an abrupt change in doping in spite of the Au seed particle acting as a buffer of the doping atoms. Due to the surface pinning of the InP and the high flow of Sn, only a fraction of the available Sn needs to be incorporated into the nanowire to achieve n-type degenerative doping and thereby avoiding the delay of the buffering effect in the Au.

6. The TESn flow was reduced and a section of n-doped InP with a lower doping concentration was added to the wires.

7. The flow of TESn was turned off and a short region without intentional doping was grown.

8. A flow of DEZn was added to the gas mixture in the growth reactor to achieve an extrinsic p-doped region.

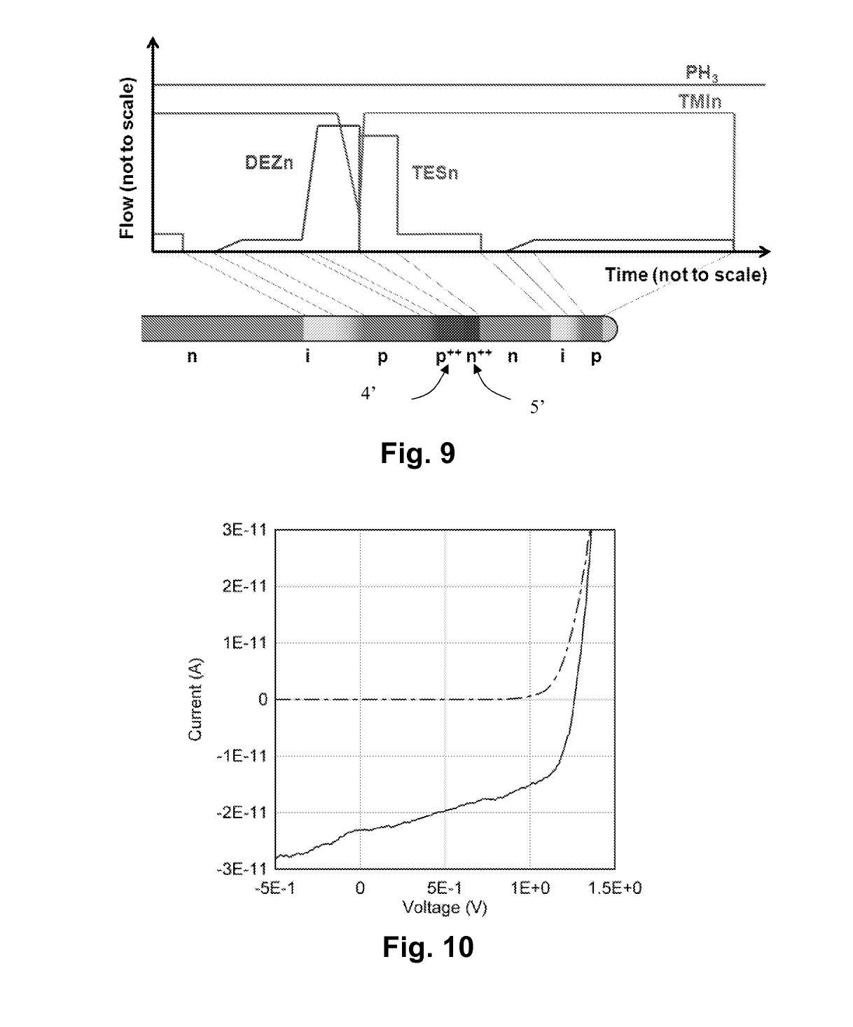

The growth temperature was kept at 420° C. throughout the whole process. A schematic diagram of the growth process is shown in FIG. 9 with the corresponding doped sections of the InP nanowire.

This growth procedure resulted in nanowires that are approximately 5 μm tall and 60 nm wide.

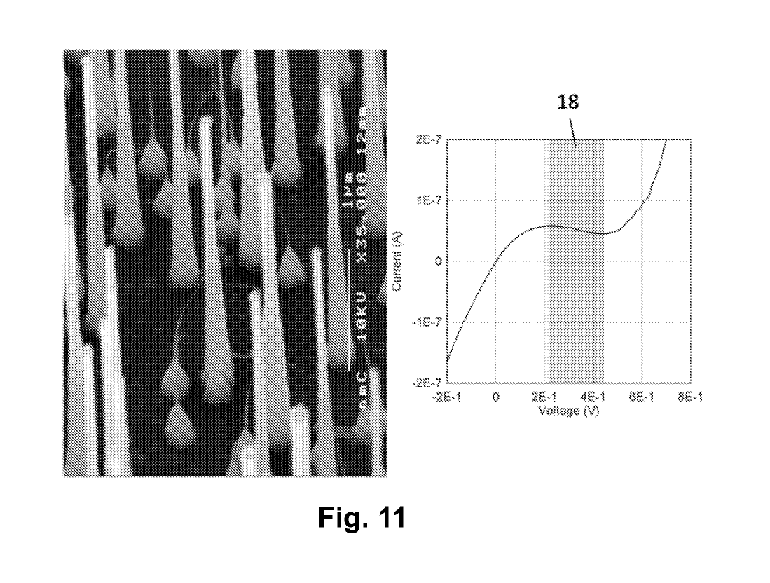

A single wire was broken off from the silicon substrate and metal contacts were made to each end of the wire. This device was investigated by measuring the current through the wire as a function of the applied voltage. The measurement data can be seen in FIG. 10.

The applied voltage that is needed to keep the current through the wire at 0 A is known as the open-circuit voltage (V_{OC}). For this device, this was 1.26 V with the light conditions for this experiment. The relatively high Voc proves the functionality of the tunnel diode as this would not be possible if the two rectifying diodes were not contacted in series through the tunnel diode. This type of device is known as a tandem photovoltaic cell.

### EXAMPLE 2

In this example, type-II heterojunction InP-GaAs nanowires were grown on an InP substrate. It should be noted that this is a material combination that is not possible for epitaxial thin-film growth without the formation of defects very shortly after the InP-GaAs interface due to the large lattice mismatch between InP and GaAs. The staggered gap material combination lowers the tunnel barrier in the junction. FIG. 11 shows a SEM picture (left) of nanowire heterojunction tunnel diodes made up by n-type InP (lower part of wire) and p-type GaAs (top part of wire).

Fabrication of the structures of FIG. 11 comprised the steps of:

1. Initiating the growth of the wires by supplying TMIn, PH3 and TESn to the growth reactor. TMIn and PH3 are the precursors for the InP, while Sn is incorporated from the TESn precursor, resulting in degenerate n-doping of the InP. The growth temperature was 420° C.

2. Stopping the flow of TMIn, PH3 and TEsn and instead adding flows of TMGa, AsH3 and DEZn. This resulted in a section of degenerately p-doped GaAs. The combination of the relatively low growth temperature and the ratio between AsH3, DEZn and TMGa resulted in an insignificant sidewall growth of GaAs. Further, the DEZn flow was chosen to be as high as possible while maintaining epitaxial growth. This, together with GaAs being easier to dope p-type than n-type, resulted in a very abrupt change in doping type. In nanowire growth, the switch from P-based material to As-based can be extremely abrupt. Also, the incorporation of Ga is not delayed by the Au seed particle as much as In. These effects lead to an abrupt change in composition between the two sections of the tunnel diode.

The function of this device was investigated by breaking of single wires and contacting each end. The current through a single wire as a function of the applied voltage can be seen in FIG. Z (right). For a range of voltages, the NDR region 18, the device shows the characteristics of negative differential resistance. Thereby, this device functions as a heterojunction tunnel diode in a III-V nanowire.

The materials in the above description are intended as examples. The actual choice of materials will depend on detailed analyses and experiments, to achieve ideal band gaps, desired voltage-current performance, etc.

However, suitable materials for the substrate include, but are not limited to: Si, Ge, SiGe, GaAs, GaP, GaAs, InAs, InP, GaN, Al₂O₃, SiC, GaSb, ZnO, InSb, SOI (silicon-on-insulator), CdS, ZnSe, CdTe.

Suitable materials for the nanowires and nanowire segments include, but are not limited to: GaInAsPSb, GaAsSb, InAsSb, GaPSb, InPSb, GaAsPSb, InAsPSb, InGaAsP, InGaAsSb, InGaPSb, InGaAsPSb AlGaInN, AlInP, BN, GaInP, GaSb, GaAs, GaAsP, GaAlInP, GaN, GaP, GaInAs, GaInN, GaAlInP, GaAlInAsP, GaInSb, Ge, InAs, InN, InP, InAsP, InSb, Si, ZnO. Possible donor dopants are Si, Sn, Te, Se, S, etc, and acceptor dopants are Zn, Fe, Mg, Be, Cd, etc.

According to common nomenclature regarding chemical formula, a binary compound consisting of an element A and an element B is commonly denoted AB in this application. However, this should be interpreted as AₓB₁₋ₓ, where 0<x<1. The same applies to ternary, quaternary and quinary compounds. However, when mentioned in a general context, such as when referring to InGaAsSbP-materials, 0≦x≦1.

While the invention has been described in connection with what is presently considered to be the most practical and preferred embodiments, it is to be understood that the invention is not to be limited to the disclosed embodiments, on the contrary, it is intended to cover various modifications and equivalent arrangements within the appended claims.

1. A tunnel diode comprising a p-doped semiconductor region and an n-doped semiconductor region forming a pn-junction, at least part of the pn-junction is being formed within a nanowire, wherein semiconductor materials on different sides of the pn-junction are different such that a heterojunction is formed.

2. The tunnel diode according to claim 1, wherein the semiconductor materials are compound semiconductor materials

3. The tunnel diode according to claim 1, wherein the nanowire protrudes from a semiconductor substrate.

4. The tunnel diode according to claim 1, wherein the p-doped semiconductor region comprises a degenerately doped p⁺⁺ segment and the n-doped semiconductor region comprises a degenerately doped n⁺⁺ segment, one of said degenerately doped segments being epitaxially grown on the other of said degenerately doped segments.

5. The tunnel diode according to claim 4, wherein said degenerately doped segments are grown in a core-shell configuration.

6. The tunnel diode according to claim 4, wherein said degenerately doped segments are grown in an axial configuration.

7-8. (canceled)

9. The tunnel diode according to claim 1, wherein the p-doped semiconductor region and the n-doped semiconductor region comprise compound semiconductor materials formed by semiconductor materials selected from the group of: Ga, P, In, As, thereby forming a type-I (Straddling gap) heterojunction tunnel diode or a type-II (Staggered gap) heterojunction tunnel diode.

10. The tunnel diode according to claim 1, wherein the p-doped semiconductor region and the n-doped semiconductor region comprise compound semiconductor materials formed by semiconductor materials selected from the group of: Ga, P, In, As, Sb and at least one of said regions comprises a Sb-based compound semiconductor, thereby forming a type-I (Straddling gap) heterojunction tunnel diode or a type-II (Staggered gap) heterojunction tunnel diode or a type-III (Broken gap) heterojunction tunnel diode.

11. The tunnel diode according to claim 9, wherein at least one compound semiconductor material comprises Al.

12. The tunnel diode according to claim 10, wherein the p-doped semiconductor region comprises GaSb on one side of the pn-junction and the n-doped semiconductor region comprises InAs on the other side of the pn-junction.

13. The tunnel diode according to claim 10, wherein the p-doped semiconductor region comprises InSb on one side of the pn-junction and the n-doped semiconductor region comprises InAs on the other side of the pn-junction.

14. The tunnel diode according to claim 1, wherein the heterojunction is strain-compensated by a functional segment in epitaxial contact with one of the segments of the heterojunction.

15. A multi -junction solar cell comprising at least one nanowire that constitutes a light absorbing part, wherein the nanowire comprises at least a first semiconductor segment of first material and a second semiconductor segment of second material, said segments being separated by a tunnel diode according to claim 1, the first and the second semiconductor segment being adapted to absorb light in a first and a second pre-determined wavelength region of the solar spectrum, respectively.

16. A method for manufacturing a tunnel diode of a compound semiconductor material comprising the steps of:
providing a semiconductor substrate; and
growing a nanowire on the semiconductor substrate, whereby a pn-junction comprising a p-doped semiconductor region and an n-doped semiconductor region at least partly within the nanowire is formed, wherein semiconductor materials on different sides of the pn-junction are different such that a heterojunction is formed.

17. The method according to claim 16, wherein the step of growing comprises the step of degenerately doping at least a p⁺⁺ segment of the p-doped region and a n⁺⁺ segment of the n-doped region.

18. The tunnel diode according to claim 10, wherein at least one compound semiconductor material comprises Al.

19. The tunnel diode according to claim 2, wherein the compound semiconductor materials are III-V semiconductor materials.

20. The tunnel diode according to claim 3, wherein the semiconductor substrate is a silicon substrate.
